(19) United States
(12) Patent Application Publication
(10) Pub. No.: US 2009/0315163 A1
(43) Pub. Date: Dec. 24, 2009

(54) Semiconductor Die Packages with Stacked Flexible Modules Having Passive Components, Systems Using the Same, and Methods of Making the Same

(76) Inventors: Terry Johnson, Cape Elizabeth, ME (US); Doug Hawks, Escondido, CA (US); Yong Liu, Scarborough, ME (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(21) Appl. No.: 12/143,680

(22) Filed: Jun. 20, 2008

(51) Int. Cl. H01L 23/495; H01L 21/00

(52) U.S. Cl. 257/676; 438/123; 257/E23.031; 257/E21.001

(57) ABSTRACT

Disclosed are semiconductor die packages comprising flexible modules having passive components, with the flexible modules and one or more semiconductor dice disposed in a stacked relationship, systems using the same, and methods of making the same. In one exemplary package embodiment, one or more semiconductor dice are disposed on a leadframe that is disposed in a stacked relationship with the flexible module. In another embodiment, one or more semiconductor dice are attached to a surface of a flexible module.

### CROSS-REFERENCES TO RELATED APPLICATIONS

NOT APPLICABLE

### BACKGROUND OF THE INVENTION

Personal electronic products, such as cell phones, personal data assistants, digital cameras, laptops, etc, are generally comprised of several packaged semiconductor IC chips and surface mount components assembled onto interconnect substrates, such as printed circuit boards and flex substrates. There is an ever increasing demand to incorporate more functionality and features into personal electronic products and the like. This, in turn, has placed ever increasing demands on the design, size, and assembly of the interconnect substrates. As the number of assembled components increases, substrate areas and costs increase, while demand for a smaller form factor increases.

### BRIEF SUMMARY OF THE INVENTION

As part of making their invention, the inventors have recognized that there is a need to address these issues and that it would be advantageous to find ways to enable increases in functionality and features of electronic products without causing increases in substrate areas and costs, and decreases in product yields. Also, as a part of making their inventions, the inventors have recognized that many electronic products have several components that can be grouped together in several small groups that provide specific functions. For example, an electronic product often has one or more power conversion circuits, each of which typically comprises a control IC chip, an inductor, one or two capacitors, and sometimes a resistor or two. As another example, an electronic product may have an analog-to-digital circuit and/or a digital-to-analog circuit, each of which typically comprises an IC chip, and several resistors and capacitors. Also, as part of making their invention, the inventors have discovered that the substrate area required for a circuit group can be significantly decreased by incorporating the components of the circuit group into a single package.

Accordingly, a first general embodiment of the invention is directed to a semiconductor die package broadly comprising a leadframe having a first surface, a second surface, and a plurality of conductive regions disposed between its first and second surfaces, and at least one semiconductor die disposed on the first surface of the leadframe and electrically coupled to at least one conductive region of the leadframe. The first exemplary embodiment further comprises an electrically conductive layer having a first surface, a second surface, and a plurality of conductive regions disposed between its first and second surfaces, and at least one passive electrical component disposed on the first surface of the electrically conductive layer and electrically coupled to at least one conductive region of the electrically conductive layer. The second surface of the electrically conductive layer is disposed over the first surface of the leadframe, and at least one conductive region of the electrically conductive layer is electrically coupled to at least one conductive region of the leadframe.

Another general embodiment of the invention is directed to a semiconductor die package broadly comprising an electrically conductive layer, at least one semiconductor die, and at least one passive electrical component. The electrically conductive layer has a first surface, a second surface, a thickness of less than about 0. 1 mm between its first and second surfaces, and a plurality of conductive regions disposed between its first and second surfaces. The at least one semiconductor die is disposed on the first surface of the electrically conductive layer and electrically coupled to at least one conductive region of the electrically conductive layer. The at least one passive electrical component is disposed on the second surface of the electrically conductive layer and electrically coupled to at least one conductive region of the electrically conductive layer.

Another general embodiment of the invention is directed to a method of manufacturing an electronic package broadly comprising forming a conductive layer on a first surface of a sacrificial leadframe, the conductive layer having a plurality of conductive regions, assembling at least one electrical component and the conductive layer together such that at least one electrically conductive region of the at least one electrical component is electrically coupled with a conductive region of the leadframe, disposing an electrically insulating material on at least a portion of the at least one electrical component and at least a portion of the conductive layer, and separating the conductive layer and the at least one electrical component from the sacrificial leadframe.

Another general embodiment of the invention is directed to a method of manufacturing an electronic package broadly comprising assembling at least one semiconductor die and flexible module together, the flexible module having a conductive layer and at least one passive electrical component electrically coupled to at least one electrically conductive region of the conductive layer.

The present invention also encompasses systems that include packages according to the present invention, each such system having an interconnect substrate and a semiconductor die package according to the present invention attached to the interconnect substrate, with electrical connections made therewith.

The invention enables the manufacture of ultra-miniature buck converters and other circuits to be made with board footprints as small as 2.5 mm by 2.5 mm, which can be used in portable consumer products, such as cell phones, MP3 players, PDA's, and the like.

The above general embodiments and other embodiments of the invention are described in the Detailed Description with reference to the Figures. In the Figures, like numerals may reference like elements and descriptions of some elements may not be repeated.

### BRIEF DESCRIPTION OF THE DRAWINGS

FIG. 1 shows a schematic diagram of an exemplary circuit group that may be incorporated into a package according to the present invention.

FIG. 2 shows a bottom perspective view of an exemplary semiconductor die package according to the present invention.

FIG. 3 shows a side view of the exemplary semiconductor die package of FIG. 2 according to the present invention.

FIG. 4 shows a top plan view of the exemplary semiconductor die package of FIG. 2 according to the present invention.

FIGS. 5-10 show side views of the exemplary semiconductor die package of FIGS. 2-4 during exemplary stages of a manufacturing process according to the invention.

FIG. 11 shows a side view of another exemplary semiconductor die package according to the present invention.

FIG. 12 shows a bottom view of a flexible module of the exemplary semiconductor die package shown in FIG. 11 according to the present invention.

FIG. 13 shows a perspective view of a semiconductor die package attached to an interconnect substrate of a system according to the present invention.

### DETAILED DESCRIPTION OF THE INVENTION

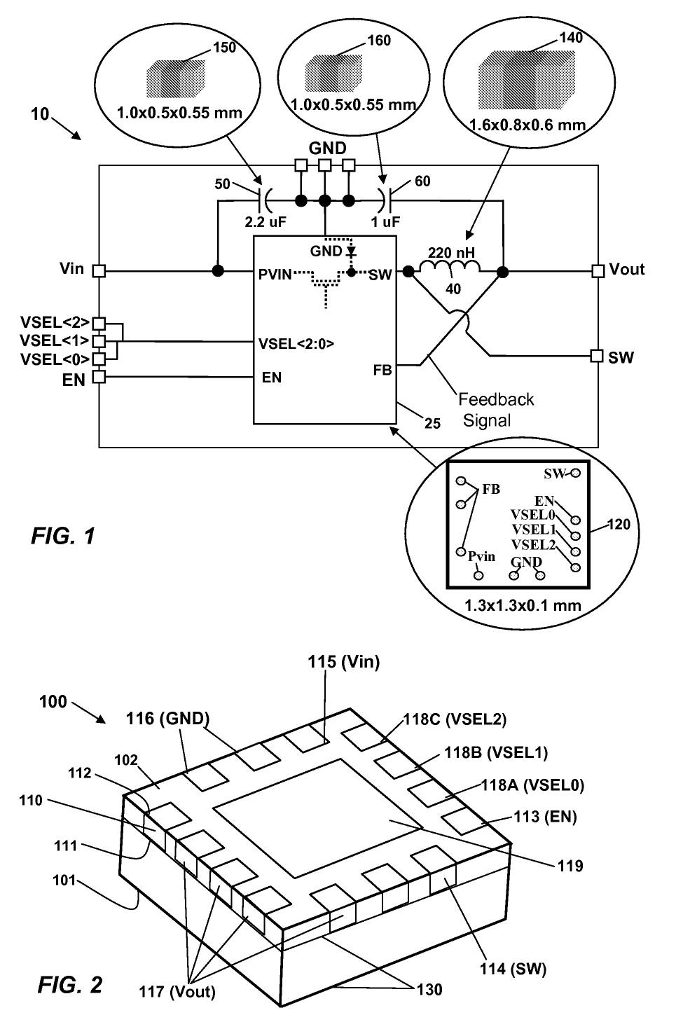

FIG. 1 shows a schematic diagram of an exemplary circuit group 10 that may be incorporated into a package according to the present invention. For illustration purposes, and without loss of generality, circuit group 10 may comprise a power conversion circuit that receives input power provided between an input voltage terminal Vin and ground terminal GND, and generates an output power supply at a different voltage level between an output terminal Vout and the ground terminal GND. Circuit group 10 includes various control inputs provided at terminals EN and VSEL<2:0>. Circuit group 10 includes an input capacitor 50 coupled between the Vin and GND terminals, a power regulator circuit 25 coupled between input capacitor 50 and a switch terminal SW, an inductor 40 coupled between the SW and Vout terminals, and an output capacitor 60 coupled between the Vout and GND terminals. Capacitor 50 may be implemented by a surface-mount capacitor 150, regulator circuit 25 may be implemented by a semiconductor die 120, inductor 40 may be implemented by a surface-mount inductor 140, and output capacitor 60 may be implemented by a surface-mount capacitor 160. For reference, these components are illustrated in FIG. 1. Each of components 140, 150, and 160 may have a generally box or cylindrical shape, with two conduction terminals at its distal ends.

Regulator circuit 25 has eight (8) terminals, labeled as PVIN, SW, GND, EN, FB, and VSEL<2:0>, which are coupled to the other components of circuit group 10 as shown in FIG. 1. Regulator circuit 25 switches the current in the inductor 40 by switching between the input voltage (at input capacitor 50) and ground in a repeating switching cycle. Inductor 40 is charged by the input voltage input during the first part of the cycle, and discharged to ground during the second part of the cycle. Regulator circuit 25 may comprise a power MOSFET device (shown in dashed lines) to couple inductor 40 to the input voltage during the cycle's first part, and a freewheeling rectifier (shown in dashed lines) to couple inductor 40 to ground during the cycle's second part. Regulator circuit 25 has control circuitry that monitors the output voltage provided at its input feedback terminal FB, and adjusts the timing parameters of switching cycle to regulate the output voltage Vout to a target value. Semiconductor die 120 comprises the control circuitry and the power-switching devices integrated together. While a power conversion circuit is being used to illustrate the present invention, it may be appreciated that packages of the present invention may house other types of circuit groups, and that other types of semiconductor dice and surface mount components may be used.

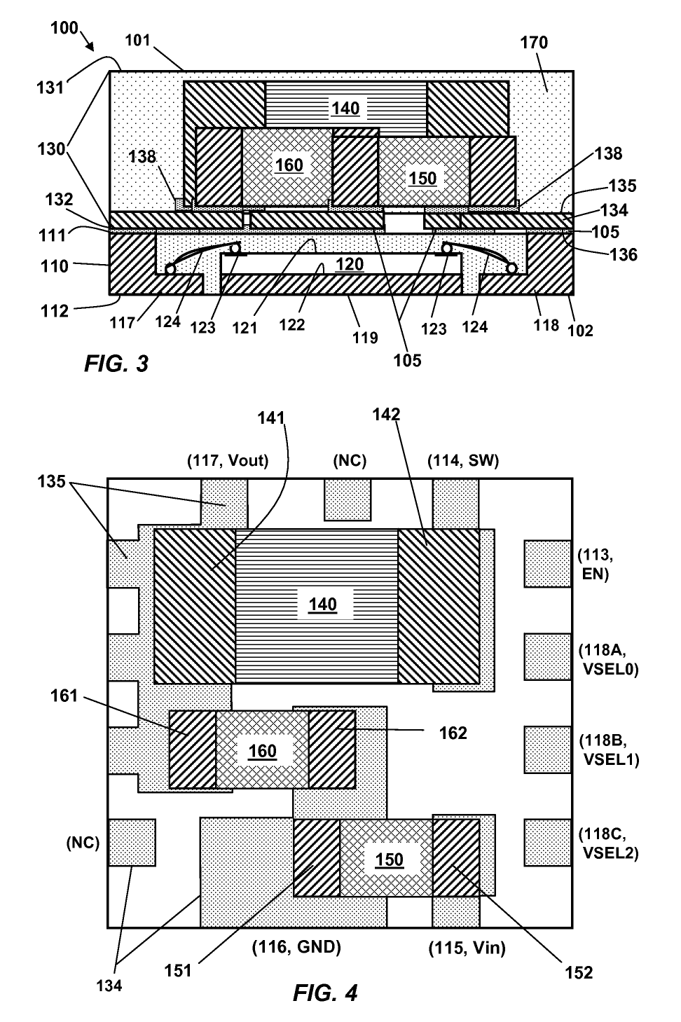

FIG. 2 shows a bottom perspective view of a first exemplary package 100 according to the present invention. Package 100 comprises a top surface 101, a bottom surface 102, and a leadframe 110, with semiconductor die 120 assembled thereon as described below in greater detail with reference to FIGS. 3-10. Leadframe 110 has a top surface 111, a bottom surface 112, a plurality of conductive regions 113-119. The leadframe's top surface 111 faces top surface 101 of package 100, and the leadframe's bottom surface 112 faces bottom surface 102 of package 100. Package 100 further comprises a flexible module 130 disposed on top surface 111 of leadframe 110. Capacitors 150, 160 and inductor 140 (shown in FIGS. 1, 3 and 4), which are passive electrical components, are assembled onto an electrically conductive layer of flexible module 130, and encased by an electrically insulating material, as described below in greater detail. Package 100 is a “leadless” microleadframe package (MLP package), where the terminal ends of the leads do not extend past the lateral edges of the molding material.

FIG. 3 is a cut-away side view of package 100 that shows components 110-170. Leadframe 110 has a recess located over conductive region 119 in which one or more semiconductor dice may be disposed. Leadframe 110 may have a thickness of about 300 μm (microns), with the recessed portion having a thickness of about 100 μm, which leave a headroom of about 200 μm for semiconductor die 120. Semiconductor die 120 has a top surface 121, a plurality of conductive regions 123 disposed on its top surface 121, and a bottom surface 122 disposed on conductive region 119 and top surface 111 of leadframe 110. Conductive region 119 may comprise a die paddle, and bottom surface 122 of die 120 may be adhered thereto with an adhesive, such as solder (not shown). Conductive regions 123 of die 120 may be electrically coupled to conductive regions 113-118 of leadframe 110 by conductive members 124, which may comprise wire bonds, ribbon bonds, tape-automated bonds (“TAB bonds”), conductive clips, and the like.

Flexible module 130 comprises a top surface 131, a bottom surface 132, an electrically conductive layer 134 disposed at bottom surface 132, and surface mount components 140, 150, and 160. Conductive layer 134 has a top surface 135, a bottom surface 136, and a plurality of conductive regions disposed therebetween, and preferably in the form of a pattern of electrical pads and traces. It has a thickness that is generally less than the thickness of a typical leadframe, being less than about 100 μm in thickness, and more generally less than about 50 μm, and typically in the range of 10 μm to 25 μm. Surface mount components 140-160 are mounted and electrically coupled to respective electrical pads of conductive layer 134 at its top surface 135. Components 140-160 may be coupled to conductive layer with bodies 138 of conductive adhesive material, such as solder. FIG. 4 shows a cut-away top plan view of flexible module 130, which shows the placement of surface mount components 140-160 in relation to the pads and traces of conductive layer 134. Inductor 140 has terminals 141 and 142, capacitor 150 has terminals 151 and 152, and capacitor 160 has terminals 161 and 162. Various pads of conductive layer 134 at the edge of the layer are coupled to conductive regions 113-118 of leadframe 110. Notations in parenthesis indicate the couplings.

Referring back to FIG. 3, an electrically insulating material 170 is disposed at the top surface 131 of flexible module 130 and over components 140-160 and over the top surface 135 of conductive layer 134. The top portion of inductor 140 may be left exposed by material 170 to enable the direct coupling of an electrically insulated heat sink for enhanced cooling and/or coupling to a electrically-insulated heat sink. A typical implementation of flexible module 130 may of a thickness of about 0.65 mm (650 microns). The bottom surface 132 of flexible module 130 is disposed over the top surface 111 of leadframe 110, with the various pads of conductive layer 134 being disposed over, and electrically coupled to, conductive regions 113-118 of leadframe 110. The various pads of conductive layer 134 may be electrically coupled to conductive regions 113-118 by bodies 105 of electrically conductive adhesive material, which may comprise solder. Direct ultrasonic bonding of pads of conductive layer 134 with conductive regions 113-118 is also possible when certain metals and alloys are used for these components, in which case bodies 105 of adhesive material are not used.

A minimum footprint of package 100 is 2.5 mm by 2.5 mm, which is 31% smaller than the typical footprint of 3 mm by 3 mm needed by an optimal discrete component implementation. A typical thickness of package 100 is about 0.95 mm. While this thickness is larger than the thickness of about 0.6 mm for the discrete components, most product applications have ample vertical space and can accommodate the larger thicknesses without difficulty. Conductive region 119 comprises a leadframe die paddle onto which semiconductor die 120 is assembled, as described below in greater detail. Conductive region 119 can be thermally coupled to an external substrate, such as by solder or thermal grease, to aid in dissipating heat generated by semiconductor die 120.

The above-described construction of package 100 enables instances of flexible module 130 to be mass produced and tested separately, and thereafter assembled together with instances of leadframe 110. This enables the use of separate optimized manufacturing processes, one for surface mount components for flexible module 130 and the other for semiconductor die for leadframe 110, and the testing of components before final assembly to increase yield.

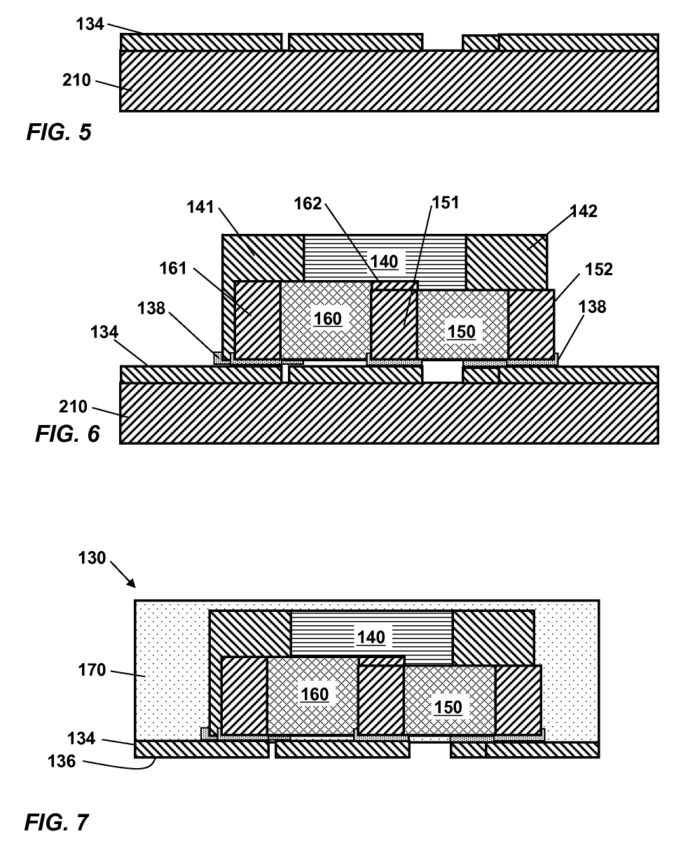

FIGS. 5-7 illustrate an exemplary method of manufacturing flexible module 130. Referring to FIG. 5, in one assembly line, an electrically conductive layer 134 is formed over a sacrificial leadframe 210, the latter of which may be whole and un-patterned. Layer 134 may be formed by plating one or more metal layers, such as layers of gold, nickel, and gold, followed by patterned etching of the plated layers through an etch mask. Layer 134 may also be formed by forming a patterned plating mask on the top surface of leadframe 210, followed by plating one or more metal layers onto the portions of leadframe 210 left exposed by the plating mask, and thereafter removing the plating mask. With layer 134 formed, solder paste or a polymer-based conductive material may be screen printed onto pad areas of the layer, and surface mount components 140-160 may be assembled onto layer 134 using conventional surface mounting equipment, with their the terminals 141, 142, 151, 152, 161, and 162 disposed on the screened areas of layer 134. The assembly may then be heated to reflow the solder paste or the cure the polymeric conductive adhesive, and to make solid electrical connections between the conductive regions of layer 134 and the terminals of components 140-160. Referring to FIG. 7, electrically insulating material 170 may then be formed over surface mount components 140-160 and the top surface of layer 134, and sacrificial leadframe 210 may removed, such as by etching, to provide a strip of instances of flexible module 130. The instances of flexible module 130 may then be separated from the strip using conventional means (singulation). Optionally, they may be electrically tested before or after separation to increase the overall manufacturing yield of package 100.

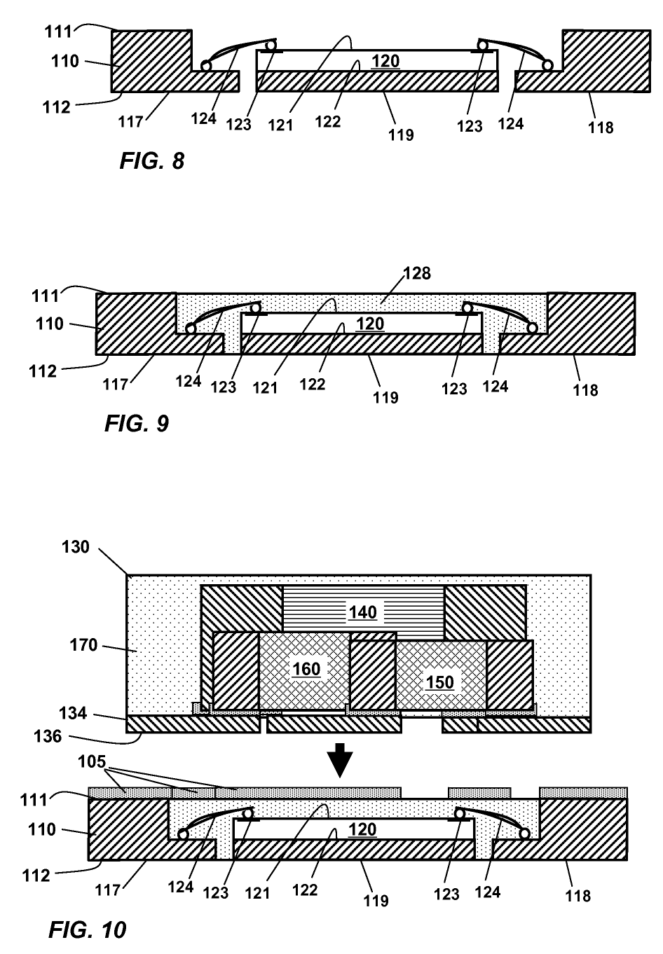

FIGS. 8-10 illustrate an exemplary method of assembling an instance of flexible module 130 with instances of leadframe 110 and semiconductor die 120 to form an instance of package 100. Referring to FIG. 8, an instance of semiconductor die 120 is disposed within the recess of an instance of leadframe 110 and over its conductive region 119, and may be attached thereto by solder, an adhesive material, or the like. Conductive members 124 may then be coupled between conductive pads 123 of the die 120 and conductive regions 113-118 of the leadframe 110. Conventional wire bonding equipment, ribbon bonding equipment, TAB bonding equipment, or the like may be used. Referring to FIG. 9, as an optional action, a body of electrically insulating material 128 may be disposed in the recess of the leadframe and over the semiconductor die and conductive members 124. A simple molding process may be used for this. A thin backing sheet adhered to the bottom surface 112 of leadframe 110 may be used to keep the molding material from covering bottom surface 112, and thereafter removed after the molding action. If the thin backing sheet is available, other well-known techniques may be used to prevent material 128 from contacting bottom surface 112. Referring to FIG. 10, a conductive adhesive material, such as solder paste or a polymer-based material, may be screen printed over top surface 111 of leadframe 110, and an instance of flexible module 130 attached thereto. A solder mask may be disposed on surface 136 of conductive layer 134 to define the bonding locations to the conductive regions 113-118 of leadframe 110. The assembly may be heated to reflow or cure the adhesive material to complete package 100, with the resulting structure shown in FIG. 3. At this point, package 100 may be separated from the frame (if present), trimmed of any flashing material, and sold to customers for use in various electrical systems.

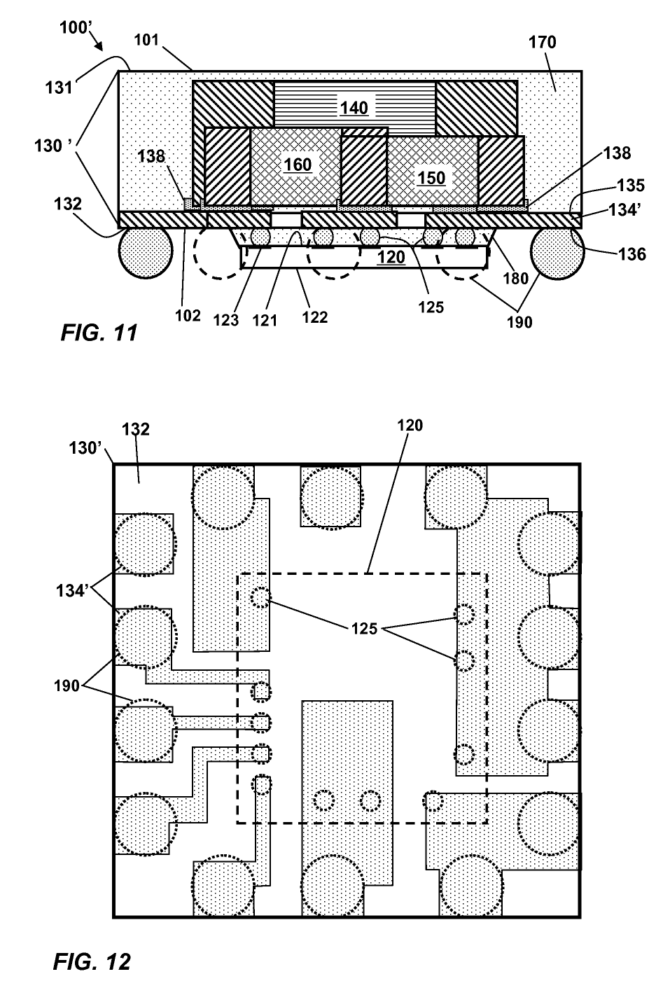

FIG. 11 shows a side view of a second exemplary package 100′ according to the present invention. Package 100′ comprises a flexible module 130′ that is similar in construction to flexible module 130 except for having a variation of conductive layer 134 that has a different layout of traces and pads, which is designated as conductive layer 134′ in the figure. The traces and pads of conductive layer 134′ are configured to enable semiconductor die 120 to be directly coupled to layer 134′, rather than to leadframe 110. As such, package 100′ does not include leadframe 110. The thicknesses for conductive layer 134′ may be the same as the thicknesses described above for conductive layer 134. Conductive pads 123 of semiconductor die 120 may be electrically coupled to inner pads of conductive layer 134′ by bodies 125 of electrically conductive adhesive material, such as solder, ultrasonically bonded gold stud bumps, or gold stud bumps bonded by an electrically conductive adhesive material disposed on the inner pads of conductive layer 134′. Also, electrically conductive bumps 190 may be disposed on the outer pads of conductive layer 134′ in some implementations of package 100′. Bumps 190 may comprise solder material, electrically conductive polymeric material, a solid metal material coupled to the pads, etc. In addition, an underfill material 180 may be disposed between semiconductor die 120 and conductive layer 134′ in some implementations of package 100′ to protect the electrical connections between die 120 and layer 134′ from corrosion. FIG. 12 shows a bottom view of a flexible module 130′ and conductive layer 134′. The locations of the layer's inner pads, the layer's outer pads, die 120, bodies 125, and bumps 190 may be seen in the figure.

With the construction of package 100′, semiconductor die 120 and bumps 190 are each disposed on bottom surface 102, and the height of bumps 190 encompasses the height of semiconductor die 130. A typical thickness of package 100′ is about 0.9 mm, including the thickness of semiconductor die 120 (typically around 0.1 mm) and the height of bumps 190 (typically around 0.25 mm). While this thickness is larger than the thickness of about 0.6 mm for the discrete components, most product applications have ample vertical space and can accommodate the larger thicknesses without difficulty. Die 120 may be left exposed, or covered by a thin protective layer having a thickness of about 0.10 mm or less, and can be thermally coupled to an external substrate, such as by thermal grease, to aid in dissipating heat.

Package 100′ may be manufactured by assembling semiconductor die 120 and flexible module 130′ together, assembling bumps 190 and flexible module 130′ together, and optionally disposing underfill material between semiconductor die 120 and flexible module 130′. Semiconductor die 120 and flexible module 130′ may be assembled together by using gold stud flip chip bonding, which provides a low profile for die 120, or by using solder bump flip-chip bonding or other bonding methods. In one form of gold stud flip chip bonding, light pressure and ultrasonic vibrations are applied to the die to form bonds between the gold stud bumps and the conductive regions. In another form of gold stud flip chip bonding, solder paste or a polymeric conductive adhesive material (e.g., conductive epoxy) is disposed on areas of surface 136 of conductive layer 134′, such as by screen printing, the gold stud bumps are contacted with these areas, and the die and leadframe are thermally compressed together to bond the gold studs with these contacted areas of conductive layer 134′ (the heat of the thermal compression reflows the solder paste or cures the polymeric adhesive material). When using solder-bump flip-chip bonding, a solder mask may be disposed on surface 136 of conductive layer 134′ to maintain reflowing solder within the attachment areas, or, before the flip-chip bonding occurs, solder bumps may be formed on die 120 and pads of solder pads may be defined on surface 136 by screen printing. Underfill material 180 may be disposed before, during, or after the assembly of die 120 with flexible module 130′. Underfill material 180 may comprise a preformed polymer sheet with conductive bodies 125 formed therein, or a uniform preformed polymer sheet through which conductive bodies 125 are pressed, such as when die 120 is assembled with module 130′ with the bodies being first disposed on die 120. Underfill material 180 may also comprise a material that is initially in liquid form, which is disposed around the sides of an assembled die 120 and wicked into the interior of the die's top surface by capillary action. The liquid underfill material then sets to a solid phase, which may be done by heat curing or chemical action. Bumps 190 and flexible module 130′ may be assembled together before or after the assembly of module 130′ with the other components. The back surface of semiconductor die 120 may be covered by a protective material (generally less than 0.05 mm thick), or left exposed to facilitate heat conduction to a substrate to which the finished package is to be attached.

Given the above description, it should be understood that, where the performance of an action of any of the methods disclosed herein is not predicated on the completion of another action, the actions may be performed in any time sequence (e.g., time order) with respect to one another, including simultaneous performance and interleaved performance of various actions. (Interleaved performance may, for example, occur when parts of two or more actions are performed in a mixed fashion.) Accordingly, it may be appreciated that, while the method claims of the present application recite sets of actions, the method claims are not limited to the order of the actions listed in the claim language, but instead cover all of the above possible orderings, including simultaneous and interleaving performance of actions and other possible orderings not explicitly described above, unless otherwise specified by the claim language (such as by explicitly stating that one action proceeds or follows another action).

As noted above, packages 100 and 100′ provide substantial space savings over discrete component implementations. As additional advantages of the packages disclosed herein, leadframe 110 and conductive layers 134, 134′ provide reduced series resistance among the components of the circuit group, and the combination of the leadframe and/or conductive layer with insulating material 160 provides more reliable electrical connections. In addition, since the packages disclosed herein provide complete functioning circuits, the packages may be tested before being assembled onto product substrates, thereby increasing yields of the product substrates. In addition, as to power supply implementations of the packages of the present invention, the configuration of the power supply components in the packages can provide conversion efficiencies of 85% or more.

While exemplary packages 100 and 100′ have been illustrated with the use of one semiconductor die, it may be appreciated that further embodiments may include two or more semiconductor die, which may be assembled onto any surface of leadframe 110 and/or any surfaces of conductive layers 134, 134′. In addition, while the above packages have been illustrated with the passive components (140, 150, and 160) being assembled onto top surfaces 136 of conductive layers 134, 134′, further embodiments may include passive components mounted on the bottom surfaces 135 of conductive layers 134, 134′, such as ultra-thin surface mount resistors.

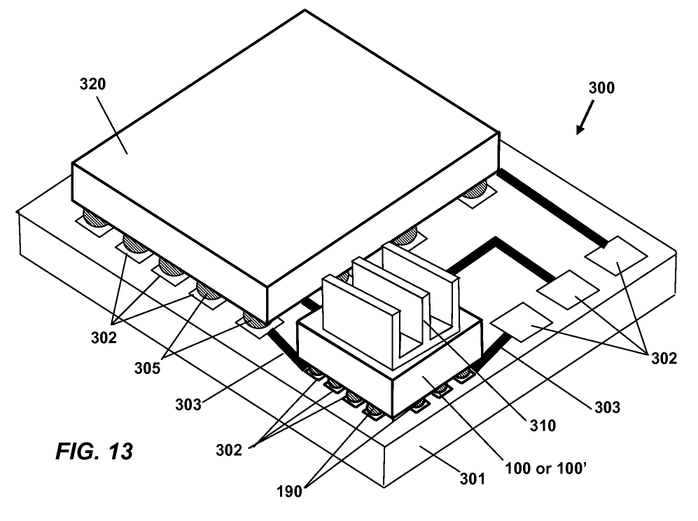

FIG. 13 shows a perspective view of a system 300 that comprises semiconductor package 100 or 100′ according to the present invention. System 300 comprises an interconnect substrate 301, a plurality of interconnect pads 302 to which components are attached, a plurality of interconnect traces 303 (only a few of which are shown for the sake of visual clarity), an instance of a package according to the invention, a second package 320, and a plurality of solder bumps 305 that interconnect the packages to the interconnect pads 302. A miniature, electrically insulated heat sink 310 may be attached to package 100 or 100′. System 300 may, or course, comprise multiple instances of packages 100 and/or 100′.

The semiconductor die packages described above can be used in electrical assemblies including circuit boards with the packages mounted thereon. They may also be used in systems such as phones, computers, etc.

Some of the examples described above are directed to “leadless”-type packages such as MLP-type packages (microleadframe packages) where the terminal ends of the leads do not extend past the lateral edges of the molding material. Embodiments of the invention may also include leaded packages where the leads extend past the lateral surfaces of the molding material.

Any recitation of “a”, “an”, and “the” is intended to mean one or more unless specifically indicated to the contrary.

The terms and expressions which have been employed herein are used as terms of description and not of limitation, and there is no intention in the use of such terms and expressions of excluding equivalents of the features shown and described, it being recognized that various modifications are possible within the scope of the invention claimed.

Moreover, one or more features of one or more embodiments of the invention may be combined with one or more features of other embodiments of the invention without departing from the scope of the invention.

While the present invention has been particularly described with respect to the illustrated embodiments, it will be appreciated that various alterations, modifications, adaptations, and equivalent arrangements may be made based on the present disclosure, and are intended to be within the scope of the invention and the appended claims.

What is claimed is:

1. A semiconductor die package comprising:
a leadframe having a first surface, a second surface, and a plurality of conductive regions disposed between its first and second surfaces;
at least one semiconductor die disposed on the first surface of the leadframe and electrically coupled to at least one conductive region of the leadframe;
an electrically conductive layer having a first surface, a second surface, and a plurality of conductive regions disposed between its first and second surfaces; and
at least one passive electrical component disposed on the first surface of the electrically conductive layer and electrically coupled to at least one conductive region of the electrically conductive layer; and
wherein the second surface of the electrically conductive layer is disposed over the first surface of the leadframe, and wherein at least one conductive region of the electrically conductive layer is electrically coupled to at least one conductive region of the leadframe.

2. The semiconductor die package of claim 1, wherein the at least one semiconductor die has a first conductive region electrically coupled to a first conductive region of the leadframe, and wherein a conductive region of the electrically conductive layer is electrically coupled to the first conductive region of the leadframe.

3. The semiconductor die package of claim 1, wherein the at least one passive electrical component comprises one of an inductor or a capacitor.

4. The semiconductor die package of claim 1, further comprising at least one electrically conductive bump disposed on a conductive region of the leadframe at the second surface of the leadframe.

5. The semiconductor die package of claim 1, wherein the leadframe comprises a recess in its first surface, and wherein the at least one semiconductor die is disposed in the recess.

6. The semiconductor die package of claim 1, further comprising a plurality of electrically conductive members electrically coupled between conductive regions of the at least one semiconductor die and conductive regions of the leadframe.

7. The semiconductor die package of claim 1, wherein the conductive layer has a thickness of less than about 0.05 mm.

8. A system comprising an interconnect substrate and the semiconductor die package of claim 1 attached to the interconnect substrate.

9. A semiconductor die package comprising:
an electrically conductive layer having a first surface, a second surface, and a plurality of conductive regions disposed between its first and second surfaces;
at least one passive electrical component disposed on the first surface of the electrically conductive layer and electrically coupled to at least one conductive region of the electrically conductive layer; and
at least one semiconductor die disposed on the second surface of the electrically conductive layer and electrically coupled to at least one conductive region of the electrically conductive layer.

10. The semiconductor die package of claim 9, wherein at least one conductive region of the at least one semiconductor is electrically coupled to a conductive region of the electrically conductive layer by a gold stud bump.

11. The semiconductor die package of claim 9, wherein the at least one passive electrical component comprises one of an inductor or a capacitor.

12. The semiconductor die package of claim 9, further comprising at least one electrically conductive bump disposed on a conductive region of the conductive layer at the second surface of the conductive layer.

13. The semiconductor die package of claim 9, further comprising a body of underfill material disposed between the at least one semiconductor die and the leadframe.

14. A system comprising an interconnect substrate and the semiconductor die package of claim 9 attached to the interconnect substrate.

15. A method of manufacturing an electronic package, the method comprising:
forming a conductive layer on a first surface of a sacrificial leadframe, the conductive layer having a plurality of conductive regions;
assembling at least one electrical component and the conductive layer together such that at least one electrically conductive region of the at least one electrical component is electrically coupled with a conductive region of the leadframe;
disposing an electrically insulating material on at least a portion of the at least one electrical component and at least a portion of the conductive layer; and
separating the conductive layer and the at least one electrical component from the sacrificial leadframe.

16. The method of claim 15, wherein the at least one electrical component comprises a passive electrical component.

17. The method of claim 15, wherein forming the conducive layer comprises plating one or more layers of metal on the first surface of the leadframe, and etching the plated layers through a patterned etch mask.

18. The method of claim 15 forming a patterned plating mask over the first surface of the leadframe, plating one or more metal layers onto portions of the leadframe's first surface that are left exposed by the plating mask.

19. A method of manufacturing an electronic package, the method comprising:
assembling at least one semiconductor die and flexible module together, the flexible module having a conductive layer and at least one passive electrical component electrically coupled to at least one electrically conductive region of the conductive layer.

20. The method of claim 19 wherein assembling the at least one semiconductor die and flexible module together comprises assembling the at least one semiconductor die onto the flexible module with at least one conductive region of the semiconductor die being electrically coupled to the at least one electrically conductive region of the conductive layer.

21. The method of claim 20 wherein assembling the at least one semiconductor die and flexible module together comprises gold stud flip chip bonding.

22. The method of claim 19 wherein the at least one semiconductor die is assembled onto a leadframe, and wherein assembling the at least one semiconductor die and flexible module together comprises assembling the leadframe and the flexible module together such that at least one conductive region of the leadframe is electrically coupled to the at least one electrically conductive region of the conductive layer.
